(19) United States
(12) Patent Application Publication
(10) Pub. No.: US 2012/0212227 A1
(43) Pub. Date: Aug. 23, 2012

(54) METAL DETECTOR TARGET DISCRIMINATION IN MINERALIZED SOILS

(76) Inventor: Bruce Halcro Candy, Basket Range (AU)

(21) Appl. No.: 13/388,137

(22) PCT Filed: Jul. 28, 2010
(86) PCT No.: PCT/AU2010/000949

§ 371 Date: May 4, 2012

(30) Foreign Application Priority Data
Jul. 31, 2009 (AU) 2009903576

(51) Int. Cl. G01V 3/08; G01R 23/16

(52) U.S. Cl. 324/326

(57) ABSTRACT

This invention relates to receive electronics of a metal detector for processing a received signal from a target in a soil, the receive electronics including: processing electronics for synchronous demodulating or sampling the received signal to produce at least two substantially ground balanced signals; processing electronics for processing the at least two substantially ground balanced signals to produce at least two substantially ground balanced processed signals, a first substantially ground balanced processed signal being more indicative of a spread of a time constant density spectrum of the received signal than a second substantially ground balanced processed signal, and the second substantially ground balanced processed signal being more indicative of an average time constant of the received signal than the first substantially ground balanced processed signal; and processing electronics for processing the at least two substantially ground balanced processed signals to produce an output signal indicative of at least the spread of the time constant density spectrum.

### INCORPORATION BY REFERENCE

The following document is referred to in the present specification:

U.S. Pat. No. 5,506,506 entitled ‘Metal detector’ for detecting and discriminating between ferrous and non-ferrous targets in ground.

The entire content of this document is hereby incorporated by reference.

### TECHNICAL FIELD

This invention relates to metal detectors that have target discrimination capability in mineralised soils.

### BACKGROUND

The general forms of most metal detectors which interrogate soils are either hand-held battery operated units, conveyor-mounted units, or vehicle-mounted units. Examples of hand-held products include detectors used to locate gold, explosive land mines or ordnance, coins and treasure. Examples of conveyor-mounted units include fine gold detectors in ore mining operations, and an example of a vehicle-mounted unit includes a unit to locate buried land mines.

These electronic metal detectors usually consist of transmit electronics generating a repeating transmit signal cycle applied to an inductor, for example a transmit coil, which transmits a resulting alternating magnetic field sometimes referred to as a transmit magnetic field. Time domain metal detectors usually include switching electronics within the transmit electronics, which switches various voltages from various power sources to the transmit coil for various periods in a repeating transmit signal cycle.

Metal detectors contain receive electronics which processes a receive magnetic field to produce an indicator output, the indicator output at least indicating the presence of at least some metal targets under the influence of the transmit magnetic field.

Time domain metal detectors typically include pulse-induction (“PI”) or pulse-induction-like metal detectors, and rectangular pulse metal detectors, wherein the receive processing includes either sampling of the receive signal or synchronous demodulation over selected periods, which may include gain weighting.

Frequency domain metal detectors typically include single or multi-frequency transmission, or pulse transmission with either sine-wave weighted synchronous demodulation, or unweighted synchronous demodulation with pre synchronous demodulation band-pass and/or low-pass filtering.

Coin detectors and increasingly de-mining detectors require target discrimination, typically time constant discrimination and ferrous/non-ferrous discrimination. The latter is obtained by measuring the received “reactive X” or “in-phase P” component/signal. The problem with measuring reactive X component is that most soils contain magnetic minerals, usually known as “mineralisation”, which may produce an interfering unwanted signal of similar, or much greater, magnitude than the target reactive X signal. As the magnitude of the soil reactive X signal is randomly distributed, a stronger soil reactive X signal than the target reactive X signal can make it impossible to distinguish target reactive X signal from soil reactive X signal, and hence make target ferrous/non-ferrous discrimination impossible. In contrast, in most soils except for some saline soils, soil “resistive R” or “quadrature-phase Q” component/signal is considerably less than the soil reactive X component, whereas target resistive R signal is typically of a similar order of magnitude to target reactive X signal. In most soils, the magnitude of reactive X signal is about one or more orders of magnitude greater than the magnitude of resistive R signal. Hence even though a target reactive X signal may be considerably smaller than soil reactive X signal, the target resistive R signal might be similar to, or even greater than, the soil resistive R signal making the target distinguishable from the soil.

Processing target R signal, and improvements in soil R rejection known as receive “ground balanced” signal processing, may result in high suppression of soil R signals compared to target R signals. Thus, any discrimination method using target R signals or “ground balanced” signals only, and not X, will result in considerable improvement in terms of discrimination target soil buried depth capability.

U.S. Pat. No. 5,506,506 discloses a discrimination method which demodulates at least two (e.g. three) different frequencies in the frequency domain, or “equivalent” in the time domain to give three different “time constant” sensitivity profiles derived from different samples or synchronous demodulation receive periods. These three received frequencies or three different time domain “time constant” sensitivity profiles are approximately ground balanced to typical magnetic soils in which X is typically more than one order of magnitude greater than R. The said three signals have post-sampling or synchronous demodulation filters which include substantial low-pass filtering or averaging. If these said signals are a, b and c, U.S. Pat. No. 5,506,506 discloses a comparison of two different ratios of a, b, and c, such as for example a/b and b/c, to give an indication of the degree of target time constant distribution, or in other terms, the effective range of a spread time constant spectrum. By definition, a system of a pure resistor of value R connected to a pure inductor of value L will respond as a pure non-distributed time constant of single value L/R, e.g. as a received voltage signal, from an unloaded receive coil, proportional to exp(−tR/L) from an isolated transmitted magnetic step or impulse in the time-domain. In contrast, all metal targets, and especially ferrous targets, produce from a single impulse response a distribution of decay signals proportional to

$${\int }_{0}^{∞} F ( τ ) {e}^{- \frac{t}{τ}} d τ$$

i.e. a continuum or spread spectrum of first order time constants τ for which the first order impulse response is exp(−t/τ), where F(τ) is the time constant distribution density function. In other words, the received target decay signal due to a transmitted magnetic step or impulse includes a simultaneous range of time constant decays, including short, medium and long time constants relative to a median time constant decay.

U.S. Pat. No. 5,506,506 does point out that only 2 frequencies are required in the frequency domain for which three different ground balanced channels may be obtained; R of each frequency, R₁ and R₂, and the reactive difference X₂−X₁. For example suppose a target may be roughly represented as having three simultaneous time constants τ1, τ2 and τ3, of relative magnitude α, β, and χ, where are α, β, and χ are >0, then for transmit frequencies ω₁ and ω₂ of equal reactive voltage magnitude, the resistive response at ω₁ is proportional to

R₁=αω₁/(τ₁(ω₁²+1/τ₁²))+βω₁/(τ₂(ω₁²+1/τ₂²))+χω₁/(τ₃(ω₁²+1/τ₃²)),

and the resistive response at ω₂ is proportional to

R₂=αω₂/(τ₁(ω₂²+1/τ₁²))+βω₂/(τ₂(ω₂¹+1/τ₂²))+χω₂/(τ₃(ω₂²+1/τ₃²)),

and the reactive difference is proportional to

Xd₂₁=α{1/(ω₂²+1/τ₁²)−1/(ω₁²+1/τ₁²)}/τ₁²+β{1/(ω₂²+1/τ₂²)−1/(ω₁²+1/τ₂²)}/τ₂²+χ({(ω₂²+1/τ₃²)−1/(ω₁²+1/τ₃²)}/τ₃².

Clearly a comparison of two different ratios between any of R₁, R₂, Xd₁₂ is a function of α, β and χ and hence gives at least an indication of the degree of time constant distribution of the said target.

In the time-domain the decay receive signal to a single impulse response is

α(exp(−t/τ₁))+β(exp(−t/τ₂))+χ(exp(−t/τ₃)),

where t=0 at the impulse.

If samples are measured at t1, t2, and t3, t3>t2>t1, to give measurements proportional to

α(exp(−t1/τ₁))+β(exp(−t1/τ₂))+χ(exp(−t1/τ₃)),

α(exp(−t2/τ₁))+β(exp(−t2/τ₂))+χ(exp(−t2/τ₃)), and

α(exp(−t3/τ₁))+β(exp(−t3/τ₂))+χ(exp(−t3/]₃)).

A comparison of two different ratios of the above will give an indication of the amount of the distributed extent of the target time constant. In particular, relative to the sample at t2, the samples at t1 and t3 are greater than the best fit of a first order impulse response δ exp(−t/τ). Similarly, synchronous demodulation, which may average over ranges of receive periods e.g. t1 to t2, t2 to t3, t3 to t4, t4 to t5 etc., may give similarly useful ratios, examples of which are disclosed in U.S. Pat. No. 5,506,506.

This invention discloses an alternative form and/or improvements of target discrimination in magnetic soils.

### BRIEF SUMMARY OF THE INVENTION

According to a first aspect of the present invention, there is provided receive electronics of a metal detector for processing a received signal from a target in a soil, the receive electronics including:
processing electronics for synchronous demodulating or sampling the received signal to produce at least two substantially ground balanced signals;
processing electronics for processing the at least two substantially ground balanced signals to produce at least two substantially ground balanced processed signals, a first substantially ground balanced processed signal being more indicative of a spread of a time constant density spectrum of the received signal than a second substantially ground balanced processed signal, and the second substantially ground balanced processed signal being more indicative of an average time constant of the received signal than the first substantially ground balanced processed signal; and
processing electronics for processing the at least two substantially ground balanced processed signals to produce an output signal indicative of at least the spread of the time constant density spectrum.

In one form, the production of the first substantially ground balanced processed signal includes a process of effective subtraction of at least two functions, a first function being a function of at least a first substantially ground balanced signal and a second function being a function of at least a second substantially ground balanced signal, wherein the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

In one form, the production of the first substantially ground balanced processed signal includes a process of effective multiplication of at least two functions, a first function being a function of at least a first substantially ground balanced signal and a second function being a function of at least a second substantially ground balanced signal, wherein the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

In one form, processing of at least two substantially ground balanced processed signals includes:
normalising each substantially ground balanced processed signal to produce a corresponding normalised substantially ground balanced processed signal; and
selecting ranges of average time constant derived from at least one normalised substantially ground balanced processed signal, and ranges of the spread of the time constant density spectrum derived from at least one other normalised substantially ground balanced processed signal, to be included in or rejected from the output signal.

In one form, the selected ranges are functions of a signal-to-noise ratio of the received signal.

According to a second aspect of the present invention, there is provided a metal detector used for detecting a target in a soil including:
a) transmit electronics for generating a repeating transmit signal cycle;
b) a magnetic field transmitter connected to the transmit electronics for receiving the repeating transmit signal cycle and generating a transmitted magnetic field;
c) a magnetic field receiver for receiving a received magnetic field and providing a received signal induced by the received magnetic field;
d) receive electronics connected to the magnetic field receiver for processing the received signal, the receive electronics including:
processing electronics for synchronously demodulating or sampling the received signal to produce at least two substantially ground balanced signals;
processing electronics for processing the at least two substantially ground balanced signals to produce at least two substantially ground balanced processed signals, a first substantially ground balanced processed signal being more indicative of a spread of a time constant density spectrum of the received signal than is a second substantially ground balanced processed signal, and the second substantially ground balanced processed signal being more indicative of an average time constant of the received signal than is the first substantially ground balanced processed signal; and
processing electronics for processing the at least two substantially ground balanced processed signals to produce an output signal indicative of at least the spread of the time constant density spectrum.

In one form, the production of the first substantially ground balanced processed signal includes a process of effective subtraction of at least two functions, a first function being a function of at least a first substantially ground balanced signal and a second function being a function of at least a second substantially ground balanced signal, the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

In one form, the production of the first substantially ground balanced processed signal includes a process of effective multiplication of at least two functions, a first function being a function of at least a first substantially ground balanced signal and a second function being a function of at least a second substantially ground balanced signal, the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

In one form, the processing of at least two substantially ground balanced processed signals includes:
normalising each substantially ground balanced processed signal and
selecting ranges of average time constant derived from at least one normalised substantially ground balanced processed signal, and ranges of the spread of the time constant density spectrum derived from at least one other normalised substantially ground balanced processed signal, to be included in or rejected from the output signal.

In one form, the selected ranges are functions of a signal-to-noise ratio of the received signal.

In one form, each waveform of the repeating transmitted magnetic field includes a first period and a second period, wherein the transmitted magnetic field during the first period changes more rapidly on average than does the transmitted magnetic field during the second period.

In one form, the transmitted magnetic field in the second period remains substantially unchanged.

In one form, the receive electronics synchronous demodulates or samples the received signal during the second period.

A detailed description of one or more embodiments of the invention is provided below along with accompanying figures that illustrate, by way of example, the principles of the invention. While the invention is described in connection with such embodiments, it should be understood that the invention is not limited to any embodiment. On the contrary, the scope of the invention is limited only by the appended claims and the invention encompasses numerous alternatives, modifications, and equivalents. For the purpose of example, numerous specific details are set forth in the following description in order to provide a thorough understanding of the present invention. The present invention may be practised according to the claims without some or all of these specific details. For the purpose of clarity, technical material that is known in the technical fields related to the invention has not been described in detail so that the present invention is not unnecessarily obscured.

Throughout this specification and the claims that follow unless the context requires otherwise, the words ‘comprise’ and ‘include’ and variations such as ‘comprising’ and ‘including’ will be understood to imply the inclusion of a stated integer or group of integers but not the exclusion of any other integer or group of integers.

The reference to any prior art in this specification is not, and should not be taken as, an acknowledgment or any form of suggestion that such prior art forms part of the common general knowledge of the technical field.

To assist with the understanding of this invention, reference will now be made to the drawings:

### BRIEF DESCRIPTION OF THE DRAWINGS

FIG. 1 depicts a general block diagram of a metal detector.

FIG. 2 depicts a block electronic circuit diagram of one embodiment of the invention with an electronic system capable of producing a repeating transmit signal cycle including a bi-polar pulse induction transmit signal, and with four synchronous demodulated receive channels.

FIG. 3 depicts example transmit and synchronous demodulation multiplication function waveforms suitable for the embodiment shown in FIG. 2.

FIG. 4 depicts an example for a non-ferrous eddy decay signal following a high voltage period, compared to a ferrous eddy decay signal of a similar median or average time constant.

### DETAILED DESCRIPTION OF THE INVENTION

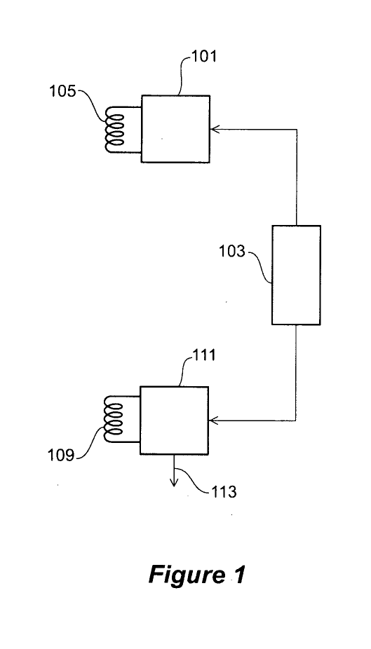

FIG. 1 is a block diagram showing the main parts of a metal detector. Transmit electronics 101 contains switches, and might also include linear elements controlled by timing electronics 103 to generate a repeating transmit signal cycle into a transmit coil 105 connected to the transmit electronics 101. The transmit coil 105 generates, in response to the repeating transmit signal cycle from transmit electronics 101, a transmitted magnetic field that illuminates a soil medium (not shown) in which there may be desired targets. A receive coil 109 which is located in the vicinity of the soil medium is connected to receive electronics 111. The received magnetic field induces a received signal in the receive coil 109 (an electromotive force or emf signal) which is processed by receive electronics 111 to generate an indicator output signal 113 indicative of at least a spread of a time constant density spectrum of the receive signal, which may indicate the presence of a target in the soil medium.

The physical form of the coil is well known to those skilled in the art and can take many forms. In one embodiment, transmit coil 105 and receive coil 109 is the same coil. Further, transmit electronics 101 and receive electronics 111 may be contained within a same electronics circuit board.

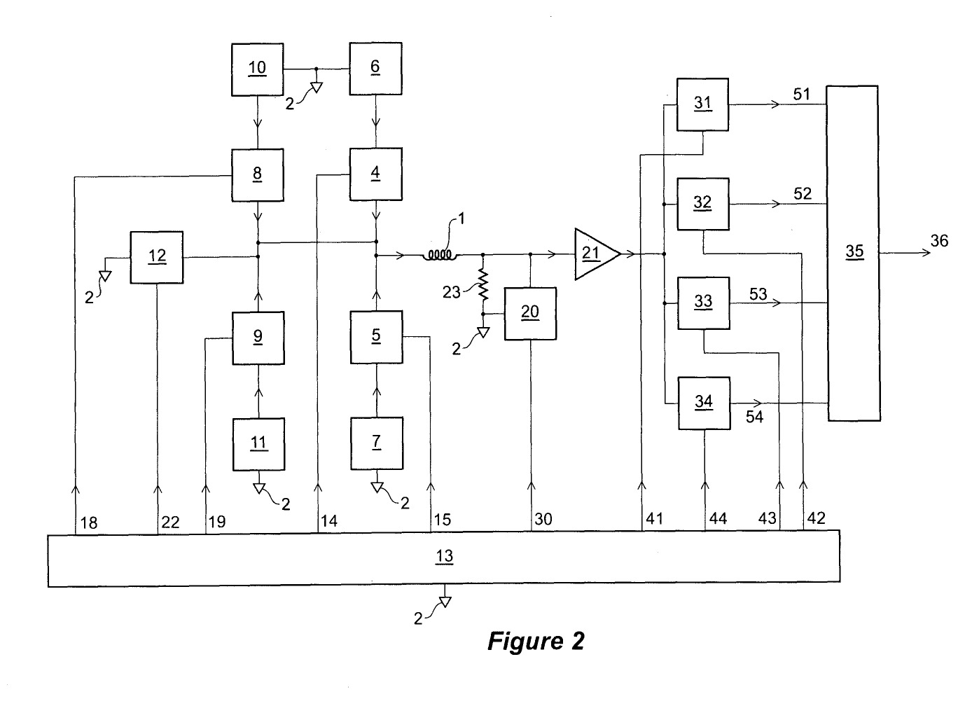

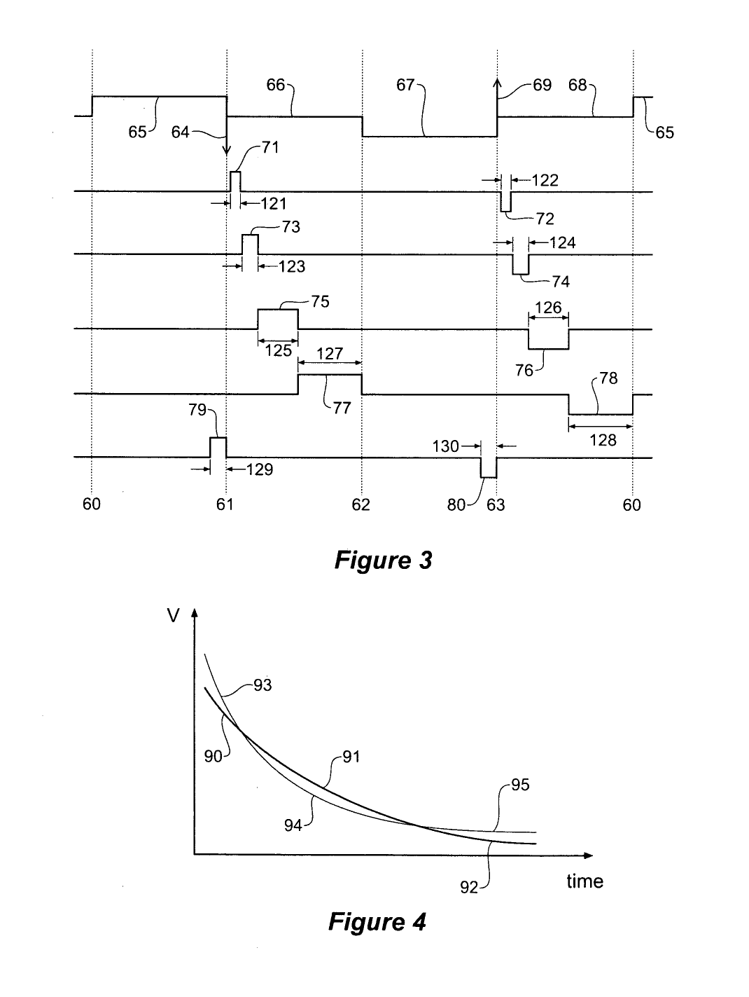

With reference to FIG. 2 and FIG. 3, a transmit and receive coil 1 is connected to switches 4, 5, 8, 9 and 12. These switches 4, 5, 8, 9 and 12 are controlled to be in a switched-on state or in a switched-off state via timing electronics 13 through controls 14, 15, 18, 19 and 22 respectively. A voltage transmit waveform of the repeating transmit signal cycle across the transmit and receive coil 1 is shown in FIGS. 3 as 65, 64, 66, 67, 69 and 68, with a change in switching at times 60, 61, 62, and 63. A low negative voltage 6from power supply 7 (e.g. −10V) is applied to the transmit and receive coil 1 by switch 5 being in a switched-on state during a period between times 62 and 63. A low positive voltage from power supply 6 (e.g. +10V) is applied to the transmit and receive coil 1 by switch 4 being in a switched-on state during a period between times 60 and 61. A high positive voltage 69 from power supply 10 (e.g. +180V) is applied to the transmit and receive coil 1 by switch 8 being in a switched-on state for a short period, not drawn to scale in FIG. 3, and shown as merely a line 69.

Thereafter between time 63 and 60, zero volts 68 is applied to the transmit and receive coil 1 when switch 12 is in a switched-on state, connecting the transmit and receive coil to the system earth 2. All the said power supplies are also connected to the system earth 2. This is a first receive period when zero transmit current flows (transmit current generally refers to the current flowing through the transmit coil). A high negative voltage 64 from power supply 11 (e.g. −180V) is applied to the transmit and receive coil 1 by switch 9 being in a switched-on state for a short period, not drawn to scale in FIG. 3, and shown as merely a line 64. Thereafter between time 61 and 62, zero volts 66 is applied to the transmit and receive coil 1 when switch 12 is in a switched-on state, connecting the transmit and receive coil to the system earth 2, and zero transmit current flows. This is a second receive period.

The transmit and receive coil 1 receives the voltage transmit waveform and generates a transmitted magnetic field. In one embodiment, the transmitted magnetic field during the period between times 60 and 61 and the period between times 62 and 63 changes more rapidly, on average, than does the transmitted magnetic field during the period between times 61 and 62 and the period between times 63 and 60. In another embodiment, the transmitted magnetic field remains unchanged during the period between times 61 and 62 and the period between times 63 and 60.

Transmit and receive coil 1 is also connected to a (shunt) transmit/receive switch 20 which is controlled to be in a switched-on state or in a switched-off state by a control signal 30 generated in the timing electronics 13. When in a switched-on state, the transmit/receive switch 20 is “shorted circuited” to zero volts, namely the system earth 2. The transmit/receive switch 20 and transmit/receive coil 1 are connected to an input of a preamplifier 21. During the first and second receive periods, the transmit/receive switch 20 is in a switched-off state. Transmit/receive switch 20 may be switched to a switched-off state between just before the end of the high voltage periods or just after the receive periods have commenced, and during the receive periods, and switched to a switched-on state, at all other times, to the system earth 2. Assuming the preamplifier 21 has a very high input impedance, then the load presented to the transmit coil is the circuitry capacitance (not shown) and resistance 23 that is connected to the system earth 2, the resistance 23 selected so as to effect critical damping of the transmit and receive coil 1.

An amplified receive signal at the output of preamplifier 21 is multiplied in the connected four synchronous demodulators, 31, 32, 33 and 34, controlled by a control signal at 41, 42, 43 and 44 respectively, all generated in the timing electronics 13. The multiplication functions are shown as a signal 71 and 72 at control line 41 for synchronous demodulator 31, and as a signal 73 and 74 at control line 42 for synchronous demodulator 32, and as a signal 75 and 76 at control line 43 for synchronous demodulator 33, and as a signal 77 and 78 at control line 44 for synchronous demodulator 34.

Synchronous demodulators 31, 32, 33 and 34 may also be sample-and-hold circuits or some other form of synchronous rectification.

FIG. 3 depicts one example of transmit and synchronous demodulation multiplication function waveforms suitable for the embodiment shown in FIG. 2. The multiplication function waveforms can take many other forms deemed suitable by a person skilled in the art.

A first synchronous demodulation multiplication function 71 and 72 multiplies the output signal of preamplifier 21 by, say, +1 during a short period 121 which commences shortly after the very short negative high voltage period at time 61, and by say −1 during a short period 122, equal in duration to the short period 121, commencing shortly after the very short positive high voltage period at time 63. The first synchronous demodulation multiplication function is zero for the rest of the time. A second synchronous demodulation multiplication function 73 and 74 multiplies the output signal of preamplifier 21 by, say, +1 during a period 123, for say double the duration of period 121 and commencing as period 121 ends, and by say −1 during a period 124, say for double the duration of period 122 and commencing as period 122 ends. The second synchronous demodulation multiplication function is zero for the rest of the time. A third synchronous demodulation multiplication function 75 and 76 multiplies the output signal of preamplifier 21 by say +1 during a period 125, say double the duration of period 123 and commencing as period 123 ends, and by say −1 during a period 126, say double the duration of period 124 and commencing as period 124 ends. The third synchronous demodulation multiplication function is zero for the rest of the time. A fourth synchronous demodulation multiplication function 77 and 78 multiplies the output signal of preamplifier 21 by say +1 during a period 127, say double the duration of period 125 and commencing as period 125 ends and ending at time 62, and by say −1 during a period 128, say double the duration of period 126 and commencing as period 126 ends and ending at time 60. The fourth synchronous demodulation multiplication function is zero for the rest of the time.

Outputs 51, 52, 53 and 54 of synchronous demodulators 31, 32, 33 and 34, respectively, are connected to processing electronics 35 for further processing, which includes at least averaging, and/or low-pass filtering to remove transmit-related signal components. This is sometimes called demodulation filtering. In one embodiment, signals s1, s2, s3 and s4 (not shown) from the post-demodulation filters connected to the outputs of synchronous demodulators, 31, 32, 33 and 34, respectively, are further processed in processing electronics 35, including discrimination algorithms to produce at least two different processed signals to produce at least an output signal 36 indicative of at least one characteristic of a metallic target. One embodiment of the output signal indicates a spread of a time constant density spectrum of the receive signal.

Herein, the term “resistive components” refers to components of the receive signal that are dependent upon the history of the transmit coil reactive voltage, but not on the instantaneous value of the transmit coil reactive voltage, and are associated with energy dissipation. In contrast, the term “reactive components” refers to components of the receive signal that are associated with energy conservation and are not dependent upon the history of the transmit coil reactive voltage, but only upon the instantaneous value of the transmit coil reactive voltage.

The signal s1, a resistive component, is responsive to all time constant targets, very short through to long. The signal s2 is responsive to all time constant targets, except very short to short time constant targets that are manifest for only a short period after the high voltage periods at times 61 and 63 and have substantially decayed before the termination of periods 121 and 122. The signal s3 is responsive to medium/long and long time constant targets, as the signal from short and short/medium time constant targets has substantially decayed to zero by the time periods 125 and 126 commence. The signal s4 is responsive only to long time constant targets, as the decay signal from short and medium time constant targets is substantially decayed to zero by the time periods 127 and 128 commence. The relationship between the frequency domain and these time domain demodulated filter outputs is complex so, for the purposes of simplicity, consider the corresponding frequency domain demodulated signals arising from the resistive components of frequencies f1, f2, f3 and f4, where f1>f2>f3>f4, the signals to be called s1, s2, s3 and s4, respectively.

The processing of s1, s2, s3 and s4 may also include high-pass or band-pass filtering in the processing electronics 35.

As s1, s2, s3 and s4 are formed when the transmit signal is zero, the signals contain no reactive components and are purely resistive. Whilst magnetic soils contain resistive components due to both mild soil conductivity and viscous superparamagnetic particles, the resistive components may be considered to be approximately ground balanced (with >95% accuracy, e.g. often >98%) as, typically, the soil reactive components are about two orders of magnitude greater than the resistive components. Thus, any processed signal formed with only s1, s2, s3 and s4 as variables may also be considered to have an approximate null ground balance to magnetic soils.

The s1, s2, s3 and s4 are further processed to provide at least a first processed signal indicative of the normalized spread of the time constant density spectrum of the receive signal, and also at least a normalized second processed signal indicative of the normalized median or average time constant of the receive signal. The normalized first and second processed signals do not need to be proportional to the normalized spread of the time constant density spectrum and the normalized median or average time constant respectively, but the first processed signal is merely required to be more indicative of a spread of a time constant density spectrum of the received signal than is the second processed signal, and the second processed signal is merely required to be more indicative of an average time constant of the received signal than is the first processed signal, so that a comparison between the first and normalized second processed signal provides an indication of the normalized spread of the time constant density spectrum relative to the median or average time constant. Although, in this embodiment, four substantially ground balanced signal (s1, s2, s3 and s4) are used to produce the two processed signals, a minimum of two substantially ground balanced signals is sufficient to obtain the desired two processed signals.

Examples of mathematical processing to provide a normalized first processed signal S₁ are: (s1−2×s2+s3)/(s1+s2+s3+s4), (s2−2×s3+s4)/(s1+s2+s3+s4), (s1−s2)/(s1+s2), (s2−s3)/(s1+s2+s3+s4), (s3−s4)/(s2+s3+s4), (s1+s2−s3−s4)/(s1+s2+s3+s4), (s1×s3−s2²)/(s1+s2+s3)², (s1×s4−s2×s3)/(s1+s2+s3+s4)², [sqrt(s1×s3)−s2]/(s1+s2+s3), [sqrt(s1×s3−s2²)]/(s1+s2+s3), (s2×s4−s3²)/(s1+s2+s3+s4)², (s1×s3−s2²+s2×s4−s3²)/(s1+s2+s3+s4)², (s1×s3−s2²)^{1/3}/(s1+s2+s3)^{2/3} . . . and so on.

In each case, the normalized spread of the time constant density spectrum is shown to include at least an effective subtractive difference between at least two terms of a function of s1, s2, s3 and s4, namely between a function more sensitive to shorter time constant receive components and a function more sensitive to longer time constant receive components of detected targets, in particular to emphasize the relative initial part of the target decay signal following the high voltage periods, as well as the longer part of the decay, compared to the middle periods. In the frequency domain, this compares resistive responses of the relatively high and low frequencies to that of the medium frequencies.

An alternative value of S₁ could be of the form (s1×s3)/s2², (s2×s4)/s3², (s1×s3+s2×s4)/(s2×s3), (s1×s3)^{1/2}/s2, (s1×s3)^{1/3}/s2^{2/3}, . . . and so on, that is without a difference between any of the terms s1, s2, s3 or s4 but rather based on products and ratios and possibly some additions, or functions of products, that is at least an effective multiplication between a function more sensitive to shorter time constant receive components and a function more sensitive to longer time constant receive components, to emphasize the relative initial part of the target decay signal following the high voltage periods, as well as the longer part of the decay, compared to the middle periods. However, the signal-to-noise ratio of this type of calculation, involving just products and ratios, is typically worse than the first examples involving at least a difference between at least two terms of a function of s1, s2, s3 and s4, because if one term, say s3 (and hence s4) is small because the target signal has decayed to near zero for these periods of demodulation owing to a fairly short time constant, then terms with just products and ratios involving s3 are highly dependent upon the signal-to-noise ratio of s3. In contrast, if s3, or say s3×s2, is added or subtracted from say s1 or say s1×s2, then the term is dominated by the stronger signal from s1 or s2, and is less dependent upon the noise in s3 or s4 than are the terms with just products and ratios.

For similar reasons, the method of employing differences between at least two terms of a function of s1, s2, s3 and s4, is better than the method suggested in U.S. Pat. No. 5,506,506 where different time constant ratios of a target are compared, e.g. s2/s1 and s3/s2.

Examples of mathematical processing to provide a (normalized) second processed signal S₂ are: (s2+s3+s4)/(s1+s2), (s3+s4)/(s2+s3), (s2+2×s3)/(2×s1+s2), (s2+2×s3+4×s4)/(4×s1+2×s2+s3), (s2/s1), (s2+s3+s4)/s1, (s2+s3)²/(s1²+s2²), (s2×s3)/(s1×s2), (s3+s4)^{2/3}/((s2²+s3²)^{1/3}), (s3²+s2(s3+s4)+s4²)/(s1+s2)², . . . and so on.

In each case the ratio is related to the mean or average time constant of a target. This ratio includes typically, sums between terms of a function of s1, s2, s3 and s4. In particular, to emphasize the difference between the relative initial part of the target decay signal following the high voltage periods and the longer part of the decay; this is equivalent to comparing the relative high and low frequency resistive components in the frequency domain.

The processing may further normalize the first processed signal relative to the second processed signal, that is by subtracting a function of the normalized second processed signal, say G(S₂), from the normalized first processed signal. G(S₂) for example may be of the form a₀+a₁×S₂+a₂×S₂²+a₃×S₂³+a₄×S₂⁴+ . . . where a₀, a₁, a₂, a₃, a₄, . . . are coefficients selected for the best fit to, say, a first order target time constant response of the normalized first processed signal versus the normalized first processed signal, so that the S₁−G(S₂)=0 for first order targets. However, instead of normalizing S₁ to first order time constant targets, it could be normalized to, say, typical non-ferrous coins. Alternatively, the processing may include a look-up table of S₁ and the corresponding S₂ for first order time constant targets, and so on, so that S₁ and S₂ may be compared to give an indication of the relative amount of spread of the time constant density spectrum to an indicator output 36. This may be in the form of, say, a visual display of a co-ordinate of S₁ and S₂, whether S₁ is normalized relative to S₂ or not. Alternatively, the indicator output signals may be an audio alert if the S₁ and S₂ values of the target fall within certain selected “discrimination ranges”. This selection may include functions of S₁ and S₂, e.g. (c₁×S₁²+c₂×S₂²)^{1/2}, or H(S₁, S₂)) where c₁ and c₂ are selected coefficients and H is a function of S₁ and S₂. The coefficients and/or functions may be varied as the signal-to-noise varies, for example to accept/include a smaller area of the S₁ and S₂ 2-D space to avoid too many false signals, or accept/include a larger space to avoid not detecting desired targets.

The target characterization may be extended further than the normalized spread of the time constant density spectrum of a target, S₁, and the normalized median or average time constant of the target, S₂, to include other characteristics of the target such as the normalized reactive component to give a value of S₃. This will extend the discrimination to “3-D space.” However, if S₃ is the normalized reactive component, the accuracy of S₃ will depend highly on the strength of the target signal compared to the detected reactive component of the soil. This usually restricts accuracy of discrimination to significantly less than the “air” detection range. Again, the discrimination acceptance or rejection volume of the 3-D space may be a function of S₁, S₂ and S₃. An example of S₃ may be say X {1+s4/(s1+s2+s3)}/(s1+s2+s3+s4), where X is the measured reactive component. An example of a synchronous multiplication function is given in FIG. 3 for a receive signal from a separate receive coil as 79 (say +1) and 80 (say −1).

The difference (or sum) between at least two terms of a function of s1, s2, s3 and s4 may be calculated entirely in, say, digital processors, or may in part be intrinsic to the synchronous demodulation multiplication functions. E.g. s1-s2 may be formed by inverting the synchronous demodulation multiplication function 73 and 74 and adding it to the synchronous demodulation multiplication function 71 and 72.

FIG. 4 shows a decay signal following a high voltage period for, say, a non-ferrous coin is given as 90, 91 and 92, while 93, 94 and 95 indicate the equivalent for a ferrous target, for a similar median or average time constant. As can be seen, the ferrous target has relatively more “fast 93” and “slow 95” eddy decay components compared to “medium 94” decay components, when compared to the corresponding non-ferrous “fast 90” and “slow 92” eddy decay components compared to “medium 91”. S₁ yields a measurement related to this difference, compared to S₂ which yields a measurement related to the median or average target time constant.

It will be appreciated by those skilled in the art that the invention is neither restricted in its use to the particular application described, nor restricted in its preferred embodiment with regard to the particular elements and/or features described or depicted herein. It will be appreciated that various modifications can be made without departing from the principles of the invention. Therefore, the invention should be understood to include all such modifications within its scope.

1. Receive electronics of a metal detector for processing a received signal from a target in a soil, the receive electronics including:
processing electronics for synchronous demodulating or sampling the received signal to produce at least two substantially ground balanced signals;
processing electronics for processing the at least two substantially ground balanced signals to produce at least two substantially ground balanced processed signals, a first substantially ground balanced processed signal being more indicative of a spread of a time constant density spectrum of the received signal than is a second substantially ground balanced processed signal, and the second substantially ground balanced processed signal being more indicative of an average time constant of the received signal than is the first substantially ground balanced processed signal; and
processing electronics for processing the at least two substantially ground balanced processed signals to produce an output signal indicative of at least the spread of the time constant density spectrum.

2. Receive electronics according to claim 1, wherein the production of the first substantially ground balanced processed signal includes a process of effective subtraction of at least two functions, a first function being a function of at least a first substantially ground balanced signal and a second function being a function of at least a second substantially ground balanced signal, wherein the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

3. Receive electronics according to claim 1, wherein the production of the first substantially ground balanced processed signal includes a process of effective multiplication of at least two functions, a first function being a function of at least a first substantially ground balanced signal and a second function being a function of at least a second substantially ground balanced signal, the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

4. Receive electronics according to claim 1, wherein the processing of at least two substantially ground balanced processed signals includes:
normalising each substantially ground balanced processed signal to produce a corresponding normalised substantially ground balanced processed signal; and
selecting ranges of average time constant derived from at least one normalised substantially ground balanced processed signal, and ranges of the spread of the time constant density spectrum derived from at least one other normalised substantially ground balanced processed signal, to be included in or rejected from the output signal.

5. Receive electronics according to claim 4, wherein the selected ranges are functions of a signal-to-noise ratio of the received signal.

6. A metal detector used for detecting a target in a soil including:
a) transmit electronics for generating a repeating transmit signal cycle;
b) a magnetic field transmitter connected to the transmit electronics for receiving the repeating transmit signal cycle and generating a transmitted magnetic field;
c) a magnetic field receiver for receiving a received magnetic field and providing a received signal induced by the received magnetic field;
d) receive electronics connected to the magnetic field receiver for processing the received signal, the receive electronics including:
processing electronics for synchronous demodulating or sampling the received signal to produce at least two substantially ground balanced signals;
processing electronics for processing the at least two substantially ground balanced signals to produce at least two substantially ground balanced processed signals, a first substantially ground balanced processed signal being more indicative of a spread of a time constant density spectrum of the received signal than is a second substantially ground balanced processed signal, and the second substantially ground balanced processed signal being more indicative of an average time constant of the received signal than is the first substantially ground balanced processed signal; and
processing electronics for processing the at least two substantially ground balanced processed signals to produce an output signal indicative of at least the spread of the time constant density spectrum.

7. A metal detector according to claim 6, wherein the production of the first substantially ground balanced processed signal includes a process of effective subtraction of at least two functions, a first function being a function of at least a first substantially ground balanced signal and a second function being a function of at least a second substantially ground balanced signal, the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

8. A metal detector according to claim 6, wherein the production of the first substantially ground balanced processed signal includes a process of effective multiplication of at least two functions, a first function being a function of at least a first substantially ground balanced signal and a second function being a function of at least a second substantially ground balanced signal, the first substantially ground balanced signal being more sensitive to short time constant components of the receive signal than is the second substantially ground balanced signal, and the second substantially ground balanced signal being more sensitive to long time constant components of the receive signal than is the first substantially ground balanced signal.

9. A metal detector according to claim 6, wherein the processing of at least two substantially ground balanced processed signals includes:
normalising each substantially ground balanced processed signal and
selecting ranges of average time constant derived from at least one normalised substantially ground balanced processed signal, and ranges of the spread of the time constant density spectrum derived from at least one other normalised substantially ground balanced processed signal, to be included in or rejected from the output signal.

10. A metal detector according to claim 9, wherein the selected ranges are functions of a signal-to-noise ratio of the received signal.

11. A metal detector according to claim 9, wherein each waveform of the repeating transmitted magnetic field includes a first period and a second period, wherein the transmitted magnetic field during the first period changes more rapidly on average than does the transmitted magnetic field during the second period.

12. A metal detector according to claim 11, wherein the transmitted magnetic field in the second period remains substantially unchanged.

13. A metal detector according to claim 11 or 12, wherein the receive electronics synchronous demodulates or samples the received signal during the second period.
